(19) United States
(12) Patent Application Publication
(10) Pub. No.: US 2019/0318943 A1
(43) Pub. Date: Oct. 17, 2019

(54) WAFER CUTTING DEVICE AND METHOD

(71) Applicant: JIANGSU LEUVEN INSTRUMMENTS CO. LTD, Jiangsu (CN)

(72) Inventor: Kaidong XU, Jiangsu (CN)

(21) Appl. No.: 16/454,289

(22) Filed: Jun. 27, 2019

Related U.S. Application Data
(63) Continuation of application No. PCT/CN2017/099609, filed on Aug. 30, 2017.

(30) Foreign Application Priority Data
Dec. 29, 2016 (CN) 201611243214.7

(51) Int. Cl. H01L 21/67; H01L 21/02; H01L 21/304

(52) U.S. Cl. CPC H01L 21/67075; H01L 21/02019; H01L 21/67092; H01L 21/67028; H01L 21/304

(57) ABSTRACT

A wafer cutting device comprises an etching unit, a gas supply unit, and a chemical reaction liquid supply unit. The etching unit including a wafer clamp and a guide shroud. The wafer clamp includes a carrier tray and a gas passage. The carrier tray is configured to fix a wafer to be cut and is formed with a plurality of air holes, and the gas passage is disposed under the carrier tray. The guide shroud is a three-layer structure consisting of an outer layer, a middle layer and an inner layer, with a first hollow interlayer being formed between the outer layer and the middle layer and a second hollow interlayer being formed between the middle layer and the inner layer. The guide shroud is disposed over the wafer clamp with a spacing therebetween adjustable for regulating flow directions of a chemical reaction liquid and a shielding gas.

### CROSS REFERENCE TO RELATED APPLICATIONS

This is a Continuation application of International Application Serial No. PCT/CN2017/099609, filed on Aug. 30, 2017, which claims the benefit of Chinese Application No. 201611243214.7, filed on Dec. 29, 2016, the disclosures of which are hereby incorporated by reference.

### BACKGROUND

The present disclosure relates to the field of semiconductors, and in particular to a wafer cutting device and method.

During development of modern semiconductor industry, especially in the laboratory stage, due to factors such as research costs, there is often a problem that a previous process needs to be done on an apparatus for a large-size (eg. 300 mm) wafer, while a subsequent process is necessary to be performed on an apparatus for a small-size (eg. 150 mm or smaller) wafer. For example, among others, some of the most advanced processes use a deep ultraviolet lithography machine to perform fine line lithography and use the most advanced industrial equipment to perform a high-precision coating of complex components, which all need to be done on the most advanced equipment for a large-size wafer. However, these state-of-the-art techniques are not compatible with small-sized wafers, making it difficult to implement on small-sized wafers. Subsequent processes are often implemented on an apparatus for small-sized wafers, which can meet device research and development requirements. This requires cutting a large-sized wafer into a small-sized wafer so that the cut-out small-sized wafer can be subjected to subsequent processes on a corresponding apparatus. That is, the cut-out small-sized wafer needs to be compatible with its corresponding apparatus.

Wafer cutting methods currently available in the market are mainly mechanical cutting with a saw blade and laser cutting. Mechanical cutting is characterized by cutting a wafer into a rectangular or square sample in the direction of its unique lattice. Mechanical cutting is also developing arcuate cutting technology, but often produces many wafer edge defects. In addition, wafer-cutting can be performed by laser-assisted technology, called stealth-cutting technology. However, this technique also cuts rectangular or square samples mainly in the lattice direction unique to the wafer. Other shapes of wafer cutting can be achieved by complete laser cutting. However, complete laser cutting takes a long time and costs a lot.

### BRIEF SUMMARY

In order to solve the above problems, the present disclosure provides a wafer cutting device, comprising an etching unit, a gas supply unit, and a chemical reaction liquid supply unit, wherein the etching unit including a wafer clamp and a guide shroud, wherein the wafer clamp includes a carrier tray and a gas passage, and the carrier tray is configured to fix a wafer to be cut and is provided with a plurality of air holes, and the gas passage is disposed under the carrier tray; the guide shroud is a three-layer structure consisting of an outer layer, a middle layer and an inner layer with a first hollow interlayer being formed between the outer layer and the middle layer and a second hollow interlayer being formed between the middle layer and the inner layer; and the guide shroud is disposed over the wafer clamp with a spacing there between adjustable for regulating flow directions of a chemical reaction liquid and a shielding gas; the gas supply unit is connected to the guide shroud for supplying a shielding gas to the inner layer and the second hollow interlayer of the guide shroud respectively, and is also connected to the gas passage for supplying a shielding gas to the carrier tray via the air holes; and the chemical reaction liquid supply unit is connected to the guide shroud for supplying a chemical reaction liquid to the first hollow interlayer.

In the wafer cutting device of the present disclosure, preferably, the inner layer of the guide shroud is further provided with a gas outlet extending outside the guide shroud.

In the wafer cutting device of the present disclosure, it is preferable that the second hollow interlayer has a thickness of 0.1˜5 mm.

In the wafer cutting device of the present disclosure, it is preferable that a lower edge of the guide shroud has a circular and wafer shape.

In the wafer cutting device of the present disclosure, preferably, a size of the carrier tray is smaller than a size of the wafer to be cut, and the air holes are arranged in a circular and wafer shape.

In the wafer cutting device of the present disclosure, preferably, the chemical reaction liquid supply unit includes: a liquid storage tank, a recovery tank, and a pump. The chemical reaction liquid is recycled in the following way: supplying the chemical reaction liquid to the first hollow interlayer of the guide shroud by the pump; the chemical reaction liquid flows through the wafer to be cut and enters the recovery tank; after that, the chemical reaction liquid is returned to the liquid storage tank by the pump.

The disclosure also provides a wafer cutting method using a wafer cutting device comprising an etching unit, a gas supply unit and a chemical reaction liquid supply unit, the method comprising the following steps: a loading step for fixing a wafer to be cut on a carrier tray; an adjusting step for adjusting a distance between a guide shroud and the carrier tray; and a gas supply step for supplying a shielding gas to an inner layer and a second hollow interlayer of the guide shroud by the gas supply unit to maintain a constant pressure in the inner layer and the second hollow interlayer, make a pressure of the inner layer smaller than a pressure of the second hollow interlayer, and make a pressure of the second hollow interlayer larger than a pressure of an external pressure outside the guide shroud, and for passing through a gas passage and air holes a shielding gas to the carrier tray, so that the shielding gas flows through the air holes to an edge of the wafer to be cut; an etching step for supplying a chemical reaction liquid to the first hollow interlayer of the guide shroud by the chemical reaction liquid supply unit, so that the chemical reaction liquid flows to a portion of the wafer to be cut outside a portion thereof below the guide shroud to perform a wet etching on the wafer to be cut so as to obtain a target wafer; a cleaning step for switching the chemical reaction liquid in the chemical reaction liquid supply unit to ultrapure water, feeding it into the first hollow interlayer of the guide shroud to remove a residual chemical reaction solution on a surface of the target wafer; a drying step for increasing a pressure and a flow rate of the shielding gas fed into the second hollow interlayer of the guide shroud to dry the target wafer; and a picking step for lifting the guide shroud and pick up the target wafer from the carrier tray.

In the wafer cutting method of the present disclosure, preferably, when there are a plurality of target wafers, a plurality of guide shrouds of the same number and the same sizes as the target wafers and a plurality of wafer clamps of the same number as the target wafers are provided.

In the wafer cutting method of the present disclosure, it is preferable that a distance between the guide shroud and the carrier tray is 0.1˜30 mm.

In the wafer cutting method of the present disclosure, preferably, the shielding gas includes at least one of an inert gas, nitrogen gas, and a reaction gas.

According to the present disclosure, large wafers can be cut into small wafers at a lower cost, which satisfies the requirement of the research and development in the semiconductor industry that some processes are necessary to be completed in large-scale cutting-edge equipment and other processes are necessary to be completed in small-sized equipment, and is also advantageous for further reducing costs for research and development. In addition, with the arrangement of the second hollow interlayer and a precise control of the gas flow and pressure in such micro-environment, a smoother edge structure of the target wafer can be obtained and the wafer cutting quality can be further optimized and improved.

### BRIEF DESCRIPTION OF THE SEVERAL VIEWS OF THE DRAWINGS

FIG. 1 is a schematic structural view of a wafer cutting device.

FIG. 2 is a schematic structural view of a guide shroud.

FIG. 3 is a schematic illustration of the arrangement of air holes in a carrier tray.

FIG. 4 is a schematic structural view of a chemical reaction liquid supply unit in a wafer cutting device.

FIG. 5 is a flow chart of a wafer cutting method.

FIG. 6 is a schematic diagram of cutting a large wafer into a target wafer.

FIG. 7 is a schematic diagram of cutting a large wafer into a plurality of target wafers.

### DETAILED DESCRIPTION

In order to make the objects, the solutions and the advantages of the present invention clearer, the technical solutions in the embodiments of the present disclosure will be clearly and fully described in the following with reference to the accompanying drawings in the embodiments of the present disclosure. It should be appreciated that the specific embodiments are only intended to illustrate the invention rather than limiting the invention. The described embodiments are only a part of the embodiments of the invention rather than all of the embodiments. All other embodiments obtained by those of ordinary skill in the art based on the embodiments of the present disclosure without creative efforts are all within the scope of the present disclosure.

In the description of the present disclosure, it is to be understood that the orientations or positional relationships of the terms “upper”, “lower” and the like are based on the orientations or positional relationships shown in the drawings and simply for a convenient and simplified description of the invention, which do not indicate or imply that a device or a component referred to must have a particular orientation, constructed and operated in a particular orientation, and thus are not to be construed as limiting the invention.

In addition, the present disclosure provides specific examples of various processes and materials, but the invention may be practiced without these specific details, as will be understood by those skilled in the art. Unless otherwise indicated below, various portions of the device can be implemented using processes and materials well known in the art.

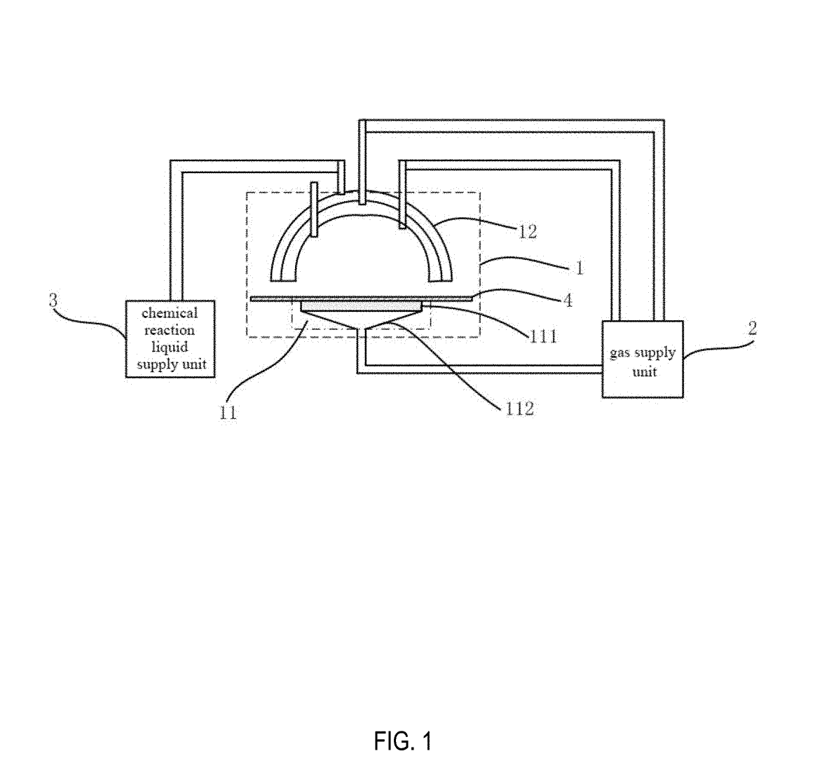

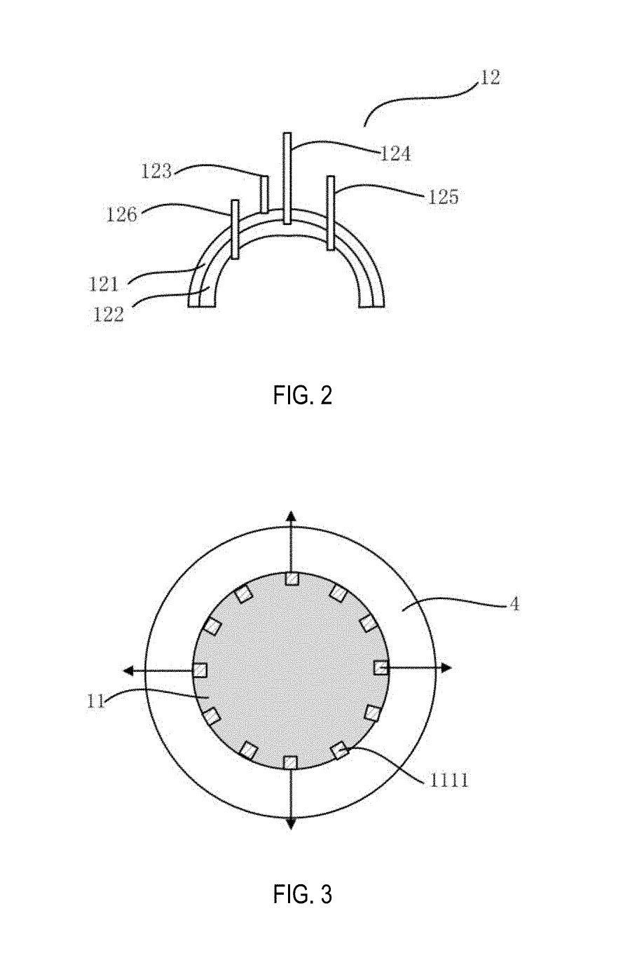

As shown in FIG. 1, a wafer cutting device includes an etching unit 1, a gas supply unit 2, and a chemical reaction liquid supply unit 3. The specific structures of the respective units are as follows. The etching unit 1 includes a wafer clamp 11 and a guide shroud 12. The wafer clamp 11 includes a carrier tray 111 and a gas passage 112. The carrier tray 111 serves to fix the wafer 4 to be cut, and a plurality of air holes 1111 (shown in FIG. 3) are formed in the carrier tray 111, and the gas passage 112 is disposed under the carrier tray. Preferably, the size of the carrier tray 111 is smaller than the size of the wafer 4 to be cut. In order to more clearly illustrate respective parts of the guide shroud, a schematic structural view of the guide shroud is shown in FIG. 2. The shroud 12 has a three-layer structure including an outer layer, a middle layer and an inner layer. A first hollow interlayer 121 is formed between the outer layer and the middle layer, and a second hollow interlayer 122 is formed between the middle layer and the inner layer. The guide shroud 12 is located above the wafer clamp 11 with a spacing therebetween adjustable to regulate the flow directions of a chemical reaction solution and a shielding gas. The outer layer of the guide shroud 12 is provided with a chemical liquid inlet 123, the middle layer is provided with a shielding gas inlet 124, and the inner layer is provided with a shielding gas inlet 125 and a shielding gas outlet 126. Among them, the shielding gas inlets 124, 125 are respectively connected to the gas supply unit 2, the chemical liquid inlet 123 is connected to the chemical reaction liquid supply unit 3, and the shielding gas outlet 126 is extended to the outside of the guide shroud 12.

Preferably, the guide shroud 12 is hemispherical in shape. It is of course also possible for the guide shroud to have a three-layer structure which is conical, cylindrical, or the like in shape with a lower edge conforming to the shape of a wafer. Furthermore, the guide shroud may have a three-layer structure of any other shape as long as the shape of the lower edge thereof conforms to the shape and the size of a desired target wafer.

Preferably, a distance between the guide shroud 12 and the wafer clamp 11 is 0.1˜30 mm.

Preferably, the second hollow interlayer 122 of the guide shroud 12 has a thickness of 0.1˜5 mm.

Preferably, the plurality of air holes 1111 in the carrier tray 111 are arranged in a shape of a wafer, as shown in FIG. 3. The flow of the shielding gas is schematically shown in FIG. 3, i.e., flowing toward the edge of the lower surface of the wafer 4 to be cut, through the air holes 1111.

The gas supply unit 2 is connected to the gas passage 112 and supplies the shielding gas to the carrier tray 111 through the air holes 1111, and is connected to the shielding gas inlets 124, 125 of the air guide shroud 12 to pass the shielding gas into the inner layer and the second hollow interlayer 122 of the guide shroud 12. The shielding gas is an inert gas such as helium, argon or the like, or nitrogen. The shielding gas supplied to the carrier tray, the shielding gas supplied to the inner layer and the second hollow interlayer of the guide shroud may be the same or different gases. For example, nitrogen is supplied to the carrier tray, argon is supplied to the inner layer of the guide shroud, or both are supplied with nitrogen. According to the requirement, the shielding gas may also be a reaction gas, a mixed gas of a reaction gas and an inert gas or a reaction gas and nitrogen gas. The reaction gas may be a gas that increases the etching speed of the wafer, such as ammonia gas, ozone gas, oxygen gas, or the like.

The chemical reaction solution supply unit 3 is connected to the guide shroud 12 and supplies a chemical reaction liquid to the first hollow interlayer 121 of the guide shroud 12. The chemical reaction solution may be any solution for quickly etching a wafer to be cut, such as a silicon wafer, for example, with an etching rate more than 1 μm/min). Commonly used reaction solutions include a mixed solution based on HF/HNO₃, or a solution based on a strong base such as NH₄OH, TMAH or the like.

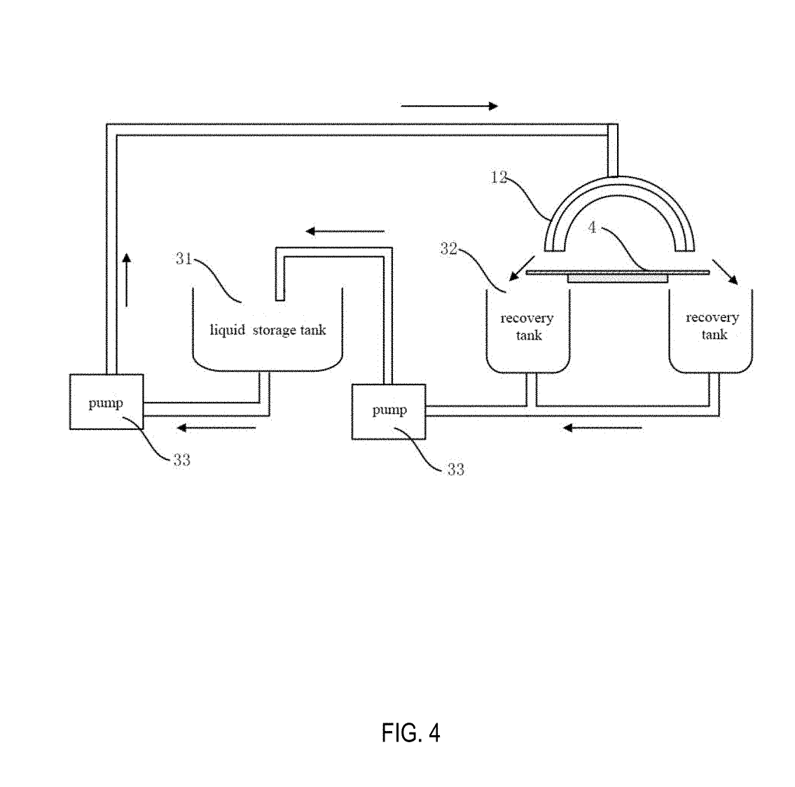

A schematic structural view of the chemical reaction liquid supply unit 3 is shown in FIG. 4. The chemical reaction liquid supply unit 3 includes a liquid storage tank 31, a recovery tank 32, and a pump 33. The chemical reaction liquid is recycled by the following way: first, the chemical reaction liquid is supplied from the liquid storage tank 31 to the first hollow interlayer 121 of the guide shroud 12 by the pump 33; after that, the chemical reaction liquid flows through the wafer 4 to be cut and flows into the recovery tank 32; finally, the chemical reaction liquid is returned to the liquid storage tank 31 by the pump 33. See the flow direction of the chemical reaction liquid indicated by the arrows in FIG. 4.

Further, the wafer cutting device may further include a heating unit that heats the chemical reaction liquid during the etching to accelerate the etching rate. Further, the shielding gas may be heated as needed.

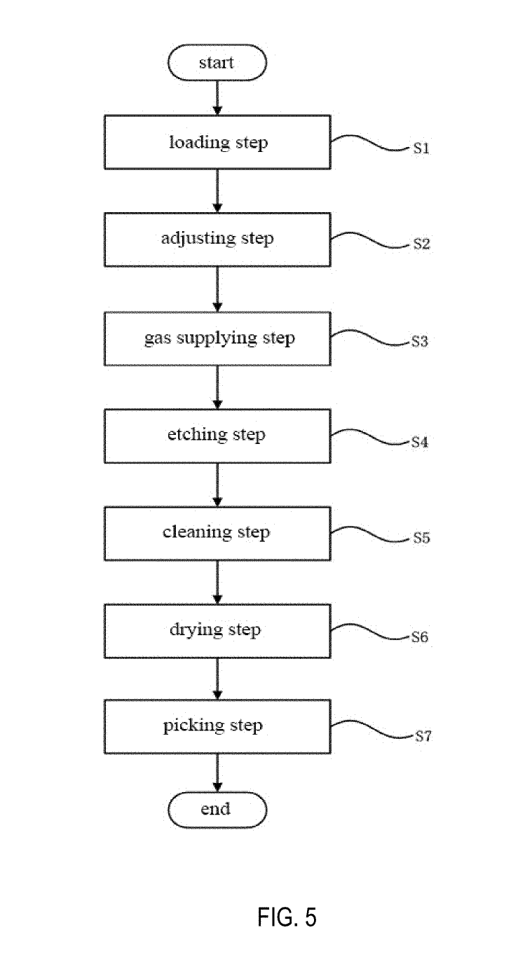

The present disclosure also provides a wafer cutting method. As shown in FIG. 5, the wafer cutting method of the present disclosure comprises a loading step S1, an adjusting step S2, a gas supply step S3, an etching step S4, a cleaning step S5, a drying step S6 and a picking step S7. Each step will be specifically described below.

In the loading step S1, the wafer 4 to be cut is fixed on the carrier tray 111. For example, it can be fixed by vacuum adsorption. Preferably, the size of the carrier tray 111 is smaller than the size of the wafer 4 to be cut.

In the adjusting step S2, a distance between the guide shroud 12 and the carrier tray 111 is adjusted to a desired distance for the process, preferably 0.1 mm to 30 mm.

In the gas supplying step S3, first, a first shielding gas is introduced into the inner layer of the guide shroud 12 from the gas supply unit 2 through the gas inlet 125, and the flow rate of the first shielding gas is kept stable, and the pressure inside the inner layer of the guide shroud 12 is kept stable. Thereafter, a second shielding gas is introduced into the second hollow interlayer 122 of the guide shroud 12 from the gas supply unit 2 through the gas inlet 124, with the flow rate of the second shielding gas being kept stable and the pressure inside the second hollow interlayer 122 of the guide shroud 12 being also kept stable. The pressure inside the second hollow interlayer 122 is kept greater than the pressure outside the guide shroud 12, typically greater than 1 standard atmosphere. Moreover, the pressure inside the second hollow interlayer 122 is kept larger than the pressure inside the inner layer of the guide shroud 12. The pressure and flow rate of the second shielding gas and the first shielding gas can be separately controlled by a gas pressure gauge and a flow meter, respectively. Since the pressure of the second shielding gas is always kept greater than the pressure of the first shielding gas, the second shielding gas can enter the inner layer of the guide shroud 12, and the inner layer of the guide shroud 12 is provided with the shielding gas outlet 126, so that the pressure inside the inner layer of the guide shroud and the pressure inside the second hollow interlayer 122 are always kept constant. Finally, a third shielding gas is supplied from the gas supply unit 2 to the carrier tray 111 through the gas passage 112 and the air holes 1111, so that the third shielding gas flows from the air holes 1111 toward the edge of the wafer 4 to be cut.

Here, the shielding gas is an inert gas such as helium gas, argon gas or the like, or nitrogen gas. The shielding gas supplied to the carrier tray and the shielding gas supplied to the inner layer of the guide shroud and the second hollow interlayer may be the same or different gases. For example, nitrogen is supplied to the carrier tray, argon is supplied to the inner layer of the guide shroud, or both the carrier tray and the inner layer of the guide shroud are supplied with nitrogen. The shielding gas may also be a reaction gas, a mixed gas of a reaction gas and an inert gas or a mixed gas of a reaction gas and nitrogen gas, as needed. The reaction gas may be a gas that increases the etching rate of the wafer, such as ammonia gas, ozone gas, oxygen gas, or the like.

In the etching step S4, the chemical reaction liquid is supplied into the first hollow interlayer 121 of the flow guide shroud 12, so that the chemical reaction liquid flows to a portion of the wafer 4 to be cut located outside the guide shroud 12 to perform wet-etching on the wafer 4 to be cut, so as to remove the portion of the wafer 4 to be cut located outside the guide shroud 12 and obtain a target wafer.

In addition, during the entire etching process, the chemical reaction liquid is always kept flowing. Due to the effect of the shielding gas supplied to the inner layer and the second hollow interlayer of the guide shroud 12, all the chemical reaction liquids are slowly blown toward the edge of the wafer 4 to be cut by the shielding gas. Therefore, a portion of the wafer 4 to be cut which is located under the guide shroud 12 is not in contact with the chemical reaction liquid. Further, preferably, the second hollow interlayer 122 has a thickness of 0.1˜5 mm. As described above, by precisely controlling the pressure and the flow rate of the shielding gas in the microenvironment, the pressure and the flow rate of the shielding gas in the second hollow interlayer are kept constant, so that a more perfect edge structure of the target wafer can be obtained.

In addition, due to the effect of the shielding gas supplied to the carrier tray 111, the lower surface of the wafer 4 to be cut is always free of chemical reaction liquid and remains dry. After etching is performed for a certain period of time, the portion of the wafer 4 to be cut which is more external than the portion that locates under the guide shroud 12 is completely etched away by the chemical reaction liquid, and the shape of the target wafer formed is exactly the same as the shape of the lower edge of the guide shroud 12.

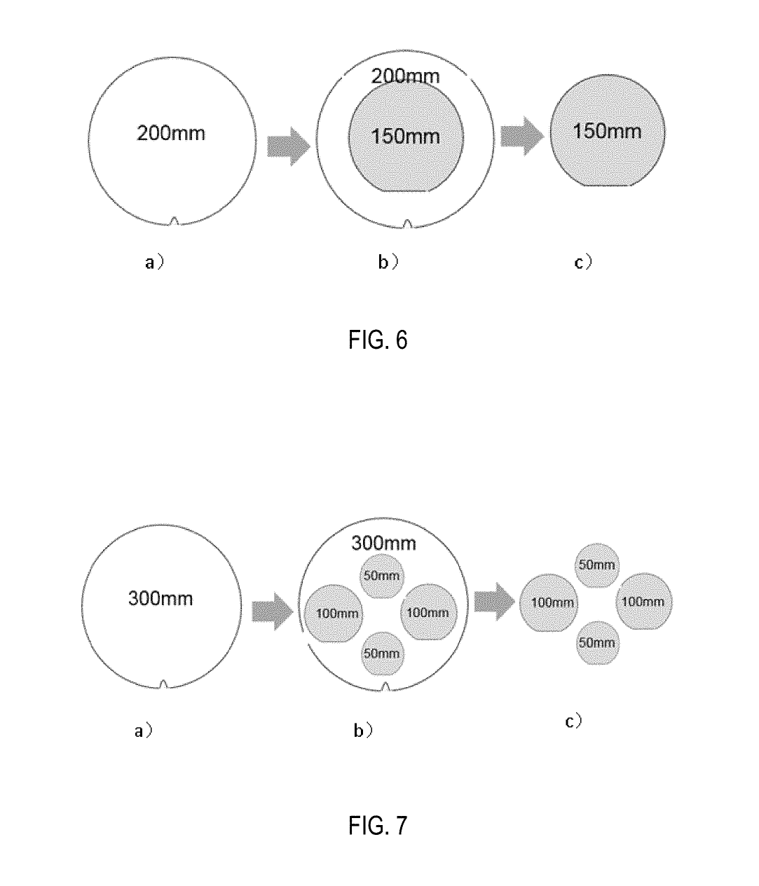

The shape and size of the guide shroud are determined according to the size of the target wafer. In a specific example, as shown in FIG. 6, the wafer to be cut has a diameter of 200 mm and the target wafer has a circular shape of a diameter of 150 mm. Therefore, a guide shroud having a circular lower edge of a diameter of 150 mm is selected accordingly. For example, it can be a three-layer structure having a conical, cylindrical, or other shape, which has a lower edge in the shape of a wafer. Preferably, the guide shroud may be hemispherical. Of course, it can also be a three-layer structure of any other shape as long as the shape of the lower edge thereof conforms to the shape and size of the desired target wafer.

A large wafer can be tailored to one or more target wafers based on the size of the initial large wafer and the size of the target wafer. The size of the target wafers may be the same or different as needed, and its size and shape are controlled by the guide shroud. As shown in FIG. 7, the large wafer to be cut has a diameter of 300 mm, and the target wafers are two small wafers having a diameter of 100 mm and two small wafers having a diameter of 50 mm. When a large wafer needs to be cut into a plurality of small wafers, a plurality of guide shrouds of the same number and in the same sizes as the target wafers are provided, and a plurality of wafer clamps of the same number as the target wafers are provided. In addition, the size of the wafer to be cut, the sizes, the number, and the like of the target wafers are not limited to the above embodiment, instead, they can be selected by those skilled in the art according to actual needs.

In the cleaning step S5, the chemical reaction liquid in the chemical reaction solution supply unit 3 is switched to ultrapure water, and the ultrapure water is introduced into the first hollow interlayer 121 of the flow guide 12 to remove the chemical reaction liquid remaining on the surface of the target wafer.

In the drying step S6, the pressure and flow rate of the second shielding gas introduced into the second hollow interlayer 122 of the flow guide 12 are increased to dry the target wafer.

In the picking step S7, the guide shroud 12 is lifted to pick up the target wafer from the carrier tray 111. For example, the vacuum adsorption is released to remove the target wafer from the carrier tray 111.

According to the present disclosure, the large wafer can be cut into small wafers at a lower cost, which satisfies the necessity in the semiconductor industry that some processes are necessary to be completed on large-scale cutting-edge equipment and other processes are necessary to be completed in small-sized equipment, and is advantageous for further reducing cost for research and development. In addition, with the arrangement of the second hollow interlayer and the precise control of the gas flow and pressure in the micro-environment thereof, the edge structure of the target wafer can be made much smoother, and the wafer cutting quality is further optimized and improved.

The above mentioned are only specific embodiments of the present invention, and the scope of the invention is not limited thereto. Instead, all other modifications or substitutions readily conceived by those skilled in the art based on the disclosure of the present application also fall within the scope of the present invention.

Disclosed are a wafer cutting device and a wafer cutting method. The wafer cutting device comprises an etching unit (1), a gas supply unit (2), and a chemical reaction liquid supply unit (3). The etching unit (1) including a wafer clamp (11) and a guide shroud (12). The wafer clamp (11) includes a carrier tray (111) and a gas passage (112).The carrier tray (111) is configured to fix a wafer (4) to be cut and is formed with a plurality of air holes (1111), and the gas passage (112) is disposed under the carrier tray (111). The guide shroud (12) is a three-layer structure consisting of an outer layer, a middle layer and an inner layer, with a first hollow interlayer (121) being formed between the outer layer and the middle layer and a second hollow interlayer (122) being formed between the middle layer and the inner layer. The guide shroud is disposed over the wafer clamp (11) with a spacing therebetween adjustable for regulating flow directions of a chemical reaction liquid and a shielding gas. According to the invention, large wafers can be cut into small wafers at a lower cost, which satisfies the requirement of the research and development in the semiconductor industry that some processes need to be completed in large-scale cutting-edge equipment and other processes need to be completed in small-sized equipment, and is advantageous for further reducing costs for research and development.

What is claimed is:

1. A wafer cutting device, comprising an etching unit, a gas supply unit, and a chemical reaction liquid supply unit, wherein
the etching unit including a wafer clamp and a guide shroud, wherein
the wafer clamp includes a carrier tray and a gas passage, and the carrier tray is configured to fix a wafer to be cut and is provided with a plurality of air holes, and the gas passage is disposed under the carrier tray;
the guide shroud is a three-layer structure consisting of an outer layer, a middle layer and an inner layer with a first hollow interlayer being formed between the outer layer and the middle layer and a second hollow interlayer being formed between the middle layer and the inner layer; and the guide shroud is disposed over the wafer clamp with a spacing therebetween adjustable for regulating flow directions of a chemical reaction liquid and a shielding gas;
the gas supply unit is connected to the guide shroud for supplying a shielding gas to the inner layer and the second hollow interlayer of the guide shroud respectively, and is also connected to the gas passage for supplying a shielding gas to the carrier tray via the air holes; and
the chemical reaction liquid supply unit is connected to the guide shroud for supplying a chemical reaction liquid to the first hollow interlayer.

2. The wafer cutting device of claim 1, wherein the inner layer of the guide shroud is further provided with a gas outlet extending outside of the guide shroud.

3. The wafer cutting device of claim 1, wherein the second hollow interlayer has a thickness of 0.1˜5 mm.

4. The wafer cutting device of claim 1, wherein a lower edge of the guide shroud has a shape of a wafer.

5. The wafer cutting device of claim 1, wherein a size of the carrier tray is smaller than a size of the wafer to be cut, and the air holes are arranged in a shape of a wafer.

6. The wafer cutting device claim 1, wherein the chemical reaction liquid supply unit includes: a liquid storage tank, a recovery tank, and a pump, and the chemical reaction liquid is recycled in the following way:
supplying the chemical reaction liquid to the first hollow interlayer of the guide shroud by the pump;
the chemical reaction liquid flows through the wafer to be cut and enters the recovery tank; and
after that, the chemical reaction liquid is returned to the liquid storage tank by the pump.

7. A wafer cutting method using a wafer cutting device which comprises an etching unit, a gas supply unit and a chemical reaction liquid supply unit, the method comprising:
a loading step for fixing a wafer to be cut on a carrier tray;
an adjusting step for adjusting a distance between a guide shroud and the carrier tray; and
a gas supplying step for supplying a shielding gas to an inner layer and a second hollow interlayer of the guide shroud by the gas supply unit to maintain a constant pressure in the inner layer and the second hollow interlayer, to make a pressure of the inner layer smaller than a pressure of the second hollow interlayer, and to make a pressure of the second hollow interlayer larger than an external pressure of the guide shroud, and to provide a shielding gas to the carrier tray via a gas passage and air holes, so that the shielding gas flows through the air holes toward an edge of the wafer to be cut;
an etching step for supplying a chemical reaction liquid to the first hollow interlayer of the guide shroud by the chemical reaction liquid supply unit, so that the chemical reaction liquid flows to a portion of the wafer to be cut which locates more external than a portion being under the guide shroud, so as to perform a wet etching on the wafer to be cut and obtain a target wafer;
a cleaning step for switching the chemical reaction liquid in the chemical reaction liquid supply unit to ultrapure water, feeding it into the first hollow interlayer of the guide shroud to remove a residual chemical reaction solution on a surface of the target wafer;
a drying step for increasing a pressure and a flow rate of the shielding gas fed into the second hollow interlayer of the guide shroud so as to dry the target wafer; and
a picking step for lifting the guide shroud and pick up the target wafer from the carrier tray.

8. The wafer cutting method of claim 7, wherein when there are a plurality of target wafers, a plurality of guide shrouds of the same number and the same sizes as the target wafers and a plurality of wafer clamps of the same number as the target wafers are provided.

9. The wafer cutting method of claim 7, wherein a distance between the guide shroud and the carrier tray is 0.1˜30 mm.

10. The wafer cutting method of claim 7, wherein the shielding gas includes at least one of an inert gas, nitrogen gas, and a reaction gas.
